(19) United States
(12) Patent Application Publication
(10) Pub. No.: US 2026/0353819 A1
(43) Pub. Date: Nov. 5, 2026

(54) SOLAR-TO-ELECTRICAL ENERGY CONVERSION SYSTEM AND METHOD OF FORMING SAME

(71) Applicant: OIP Technology Pte Ltd, Singapore (SG)

(72) Inventor: Yonggang JIN, Singapore (SG)

(21) Appl. No.: 19/539,415

(22) Filed: Feb. 13, 2026

(30) Foreign Application Priority Data
Apr. 15, 2025 (CN) 202510471052.5

(51) Int. Cl. H10F 19/50; H10D 80/20; H10D 80/30; H10F 71/00; H10W 70/05; H10W 70/06; H10W 70/09; H10W 70/60; H10W 70/63; H10W 70/652; H10W 70/685; H10W 90/10; H10W 90/22; H10W 90/28

(52) U.S. Cl. CPC H10F 19/50; H10D 80/251; H10D 80/30; H10F 71/129; H10F 71/139; H10W 70/06; H10W 70/09; H10W 70/095; H10W 70/614; H10W 70/63; H10W 70/6528; H10W 70/685; H10W 90/10; H10W 90/22; H10W 90/28

(57) ABSTRACT

Disclosed is a solar-to-electrical energy conversion system and a method of forming the system. The method includes: providing a solar cell and a number of functional chips, the solar cell having a front side and an opposing backside, each of the functional chips having a front side and an opposing backside; immobilizing the functional chips with a molded layer so that adjacent functional chips are spaced apart at intervals; forming a first passivation layer over the front sides of the functional chips and a surface of the molded layer; forming a plurality of contact vias in the first passivation layer, which are separately connected to the functional chips; forming a metal layer over a surface of the first passivation layer, which connects the functional chips through some of the contact vias; forming a second passivation layer over the surface of the first passivation layer and a surface of the metal layer and exposing surfaces of the remaining contact vias from the second passivation layer; and bonding the backside of the solar cell to a surface of the second passivation layer and connecting the backside of the solar cell to the remaining contact vias with metal wires.

### CROSS-REFERENCE TO RELATED APPLICATION

This application claims the priority of Chinese patent application number 202510471052.5, filed on Apr. 15, 2025, the entire contents of which are incorporated herein by reference.

### TECHNICAL FIELD

The present invention relates to the field of generating electricity from solar energy and, in particular, to a solar-to-electrical energy conversion system and a method of forming the system.

### BACKGROUND

Solar energy is renewable and usable for electricity generation. With the continuing growth of global economy and environmental awareness, the demand for sustainable clean energy is rising day by day, and increasing attention is being paid to solar energy as sustainable clean energy for use in electricity generation. Conversion of solar energy to electricity relies mainly on solar cells, which are electricity-generating apparatuses producing electrical currents when exposed to sunlight. In addition, solar-to-electrical energy conversion systems would also include batteries, control functions and some devices containing functional chips for current processing.

Conventional solar-to-electrical energy conversion systems include, among others, solar cells, batteries and devices containing various functional (e.g., power) and driver chips. The solar cells have front and back sides. The front sides of the solar cells are adapted to receive solar energy, and positive and negative electrodes, which are connected to positive and negative terminals of the batteries, are arranged on the backsides of the solar cells to collect electricity converted from solar energy in the batteries. The functional chip-containing devices are connected to the solar cells with transmission lines.

However, in the conventional solar-to-electrical energy conversion systems, the functional chip-containing devices are not integrated with the solar cells on a single support, but are deployed at a long distance from the solar cells and connected thereto with transmission lines. Therefore, the solar cells are distantly spaced from the functional chip-containing devices, leading to significant loss of power during transmission.

### SUMMARY

It is an object of the present invention to provide a solar-to-electrical energy conversion system with reduced power loss during photovoltaic conversion and a method of forming such a system.

To this end, the present invention provides a method of forming a solar-to-electrical energy conversion system, which includes:
providing a solar cell and a number of functional chips, the solar cell having a front side and an opposing backside, each of the functional chips having a front side and an opposing backside;
immobilizing the functional chips with a molded layer so that adjacent functional chips are spaced apart at intervals;
forming a first passivation layer over the front sides of the functional chips and a surface of the molded layer;
forming a plurality of contact vias in the first passivation layer, which are separately connected to the functional chips;
forming a metal layer over a surface of the first passivation layer, which connects the functional chips through some of the contact vias;
forming a second passivation layer over the surface of the first passivation layer and a surface of the metal layer and exposing surfaces of the remaining contact vias from the second passivation layer; and
bonding the backside of the solar cell to a surface of the second passivation layer and connecting the backside of the solar cell to the remaining contact vias with metal wires.

Optionally, in the method, the functional chips may include a power chip and a driver chip.

Optionally, in the method, immobilizing the functional chips with the molded layer may include:
providing a temporary carrier;
adhesively bonding the front sides of the functional chips to a front side of the temporary carrier with a double-sided adhesive tape so that adjacent functional chips are spaced apart at intervals;
forming the molded layer on a surface of the temporary carrier between adjacent functional chips; and
removing the double-sided adhesive tape and the temporary carrier.

Optionally, in the method, a material of the molded layer may include epoxy resin.

Optionally, in the method, adjacent functional chips may be spaced apart at intervals smaller than 20 μm.

Optionally, in the method, adjacent functional chips may be spaced apart at 15-μm intervals.

Optionally, after the functional chips are immobilized with the molded layer so that adjacent functional chips are spaced apart at intervals, the method may further includes forming wiring layers on the front sides of the functional chips.

Optionally, in the method, the contact vias may be separately connected to the wiring layers on the functional chips.

Optionally, in the method, the exposure of the surfaces of the remaining contact vias from the second passivation layer may be accomplished by openings formed in the second passivation layer.

The present invention also provides a solar-to-electrical energy conversion system formable according to the method as defined above, which includes:
a number of functional chips, which are immobilized with a molded layer so that adjacent functional chips are spaced apart at intervals;
a first passivation layer over front sides of the functional chips and a surface of the molded layer;
a plurality of contact vias in the first passivation layer, which are separately connected to the functional chips;
a metal layer over a surface of the first passivation layer, which connects the functional chips through some of the contact vias;
a second passivation layer over surfaces of the first passivation layer and the metal layer, wherein surfaces of the remaining contact vias are exposed from the second passivation layer; and
a solar cell on a surface of the second passivation layer, wherein a backside of the solar cell is connected to the remaining contact vias through metal wires.

The present invention provides a solar-to-electrical energy conversion system and a method of forming the system. The system includes: providing a solar cell and a number of functional chips, the solar cell having a front side and an opposing backside, each functional chip having a front side and an opposing backside; immobilizing the functional chips with a molded layer so that adjacent functional chips are spaced apart at distances; forming a first passivation layer over the front sides of the functional chips and a surface of the molded layer; forming a plurality of contact vias in the first passivation layer, which are separately connected to the functional chips; forming a metal layer over a surface of the first passivation layer, which connects the functional chips through some of the contact vias; forming a second passivation layer over the surface of the first passivation layer and a surface of the metal layer and exposing surfaces of the remaining contact vias from the second passivation layer; and bonding the backside of the solar cell to a surface of the second passivation layer and connecting the backside of the solar cell to the remaining contact vias with metal wires. The present invention enables the functional chips to be integrated with the solar cell with shorter transmission paths between the functional chips and between the functional chips and the solar cell, resulting in lower power consumption.

### BRIEF DESCRIPTION OF THE DRAWINGS

FIG. 1 shows a flowchart of a method of forming a solar-to-electrical energy conversion system according to embodiments of the present invention.

FIGS. 2 to 6 are schematic diagrams of structures formed during the formation of a solar-to-electrical energy conversion system according to embodiments of the present invention.

In these figures, 110 denotes a temporary carrier; 120, a power chip; 130, a driver chip; 140, a double-sided adhesive tape; 150, a molded layer; 160, a first passivation layer; 171, a first contact via; 172, a second contact via; 173, a third contact via; 174, a fourth contact via; 180, a metal layer; 190, a second passivation layer; 200, a solar cell; and 210, a metal wire.

### DETAILED DESCRIPTION

Specific embodiments of the present invention are described in greater detail below with reference to the accompanying schematic diagrams. From the following description, advantages and features of the present invention will become more apparent. Note that the figures are provided in a considerably simplified form not necessarily drawn to exact scale for the only purpose of helping to explain the disclosed embodiments in a more convenient and clearer way.

In the following, the terms “first”, “second” and the like may be used to distinguish between similar elements without necessarily implying any particular ordinal or chronological sequence. It will be understood that the terms so used are interchangeable, whenever appropriate. Likewise, if a method is described herein as including a series of steps, the order of these steps as presented herein is not necessarily the only order in which they can be performed, and some of the stated steps may be omitted and/or other steps not described herein may be added to the method.

It will be understood that when a layer (or film), region, pattern or structure is referred to as being “above” a substrate, other layer (or film), region and/or pattern, it may be directly on the other layer or substrate, or intervening layer(s) may also be present. It will also be understood that when a layer is referred to as being “under” another layer, it may be directly under or below the other layer, or one or more intervening layers may also be present. Further, reference to a layer being “above” or “under” another layer is made herein based on the orientation of the accompanying drawings.

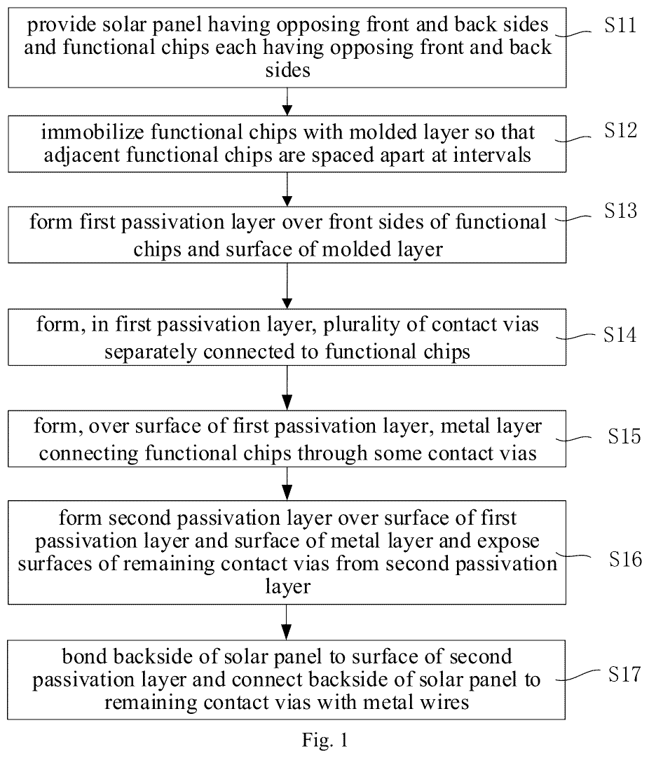

Referring to FIG. 1, the present invention provides a method of forming a solar-to-electrical energy conversion system, which includes:
S11) providing a solar cell and a number of functional chips, the solar cell having a front side and an opposing backside, each functional chip having a front side and an opposing backside;
S12) immobilizing the functional chips with a molded layer so that adjacent functional chips are spaced apart at intervals;
S13) forming a first passivation layer over the front sides of the functional chips and a surface of the molded layer;
S14) forming a plurality of contact vias in the first passivation layer, which are separately connected to the functional chips;
S15) forming a metal layer over a surface of the first passivation layer, which connects the functional chips through some of the contact vias;
S16) forming a second passivation layer over the surface of the first passivation layer and a surface of the metal layer and exposing surfaces of the remaining contact vias from the second passivation layer; and
S17) bonding the backside of the solar cell to a surface of the second passivation layer and connecting the backside of the solar cell to the remaining contact vias with metal wires.

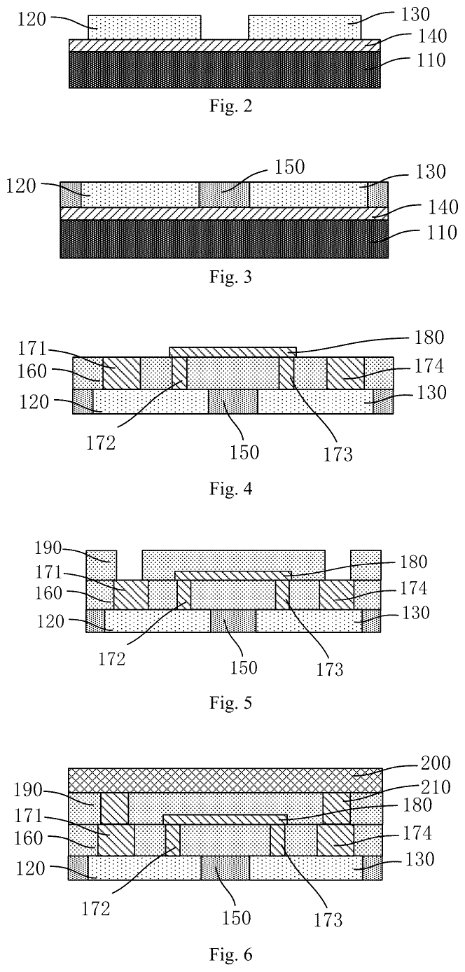

Referring to FIG. 2, first of all, a temporary carrier 110, a power chip 120 and a driver chip 130 are provided in accordance with an embodiment of the present invention. Here, the power chip 120 and the driver chip 130 are provided only as an example, and in alternative embodiments of the present invention, each of them may be replaced with a different functional chip. The temporary carrier 110 has a front side and an opposing backside, and each of the power chip 120 and the driver chip 130 also has a front side and an opposing backside. The power chip 120 and the driver chip 130 are placed on and attached to the temporary carrier 110 with a double-sided adhesive tape 140 in such a manner that their front sides are bonded to the front side of the temporary carrier 110. The power chip 120 and the driver chip 130 are spaced apart from each other at an interval smaller than 20 μm, preferably of 15 μm. A smaller distance between the power chip 120 and the driver chip 130 can lead to reduced wiring resistance.

Next, referring to FIG. 3, an injection molding process is performed on the front side of the temporary carrier 110, forming a molded layer 150 between the power chip 120 and the driver chip 130. Preferably, the surface of the molded layer 150 is flush with the surface of the power chip 120 and the surface of the driver chip 130. The molded layer 150 may be an epoxy resin layer. The molded layer 150 can immobilize the power chip 120 and the driver chip 130 relative to each other.

Subsequently, referring to FIG. 4, the double-sided adhesive tape 140 and the temporary carrier 110 are removed, and the power chip 120 and the driver chip 130 are turned upside down so that the front sides of the power chip 120 and the driver chip 130 face upwards. Wires are formed on the front sides of the power chip 120 and the driver chip 130 in the form of wiring layers respectively for subsequently electrically connecting the power chip 120 to the driver chip 130 and for subsequently electrically connecting the power chip 120 and the driver chip 130 to a solar cell. A first passivation layer 160 is then formed over the front side of the power chip 120, a surface of the molded layer 150 and the front side of the driver chip 130. A first through hole and a second through hole are formed in the first passivation layer 160 above the power chip 120. The wiring layer for electrically connecting the driver chip 130 is exposed in the first through hole, and the wiring layer for electrically connecting the solar cell in the second through hole. A third through hole and a fourth through hole are formed in the first passivation layer 160 above the driver chip 130. The wiring layer for electrically connecting the power chip 120 is exposed in the third through hole, and the wiring layer for electrically connecting the solar cell in the fourth through hole. After that, a metal material is filled in the first, second, third and fourth through holes, forming a first contact via 171, a second contact via 172, a third contact via 173 and a fourth contact via 174, respectively. The first contact via 171 is connected to the wiring layer for electrically connecting the driver chip 130, the second contact via 172 to the wiring layer for electrically connecting the solar cell, the third contact via 173 to the wiring layer for electrically connecting the power chip 120 and the fourth contact via 174 to the wiring layer for electrically connecting the solar cell.

Afterwards, with continued reference to FIG. 4, a metal layer 180 is formed on the surface of the first passivation layer 160, which electrically connects the first contact via 171 to the third contact via 173, thereby electrically connecting the power chip 120 to the driver chip 130.

After that, referring to FIG. 5, a second passivation layer 190 is formed over surfaces of the first passivation layer 160 and the metal layer 180, and the second passivation layer 190 is partially etched away, forming openings in the second passivation layer 190, which expose a surface portion of the second contact via 172 and a surface portion of the fourth contact via 174.

Next, referring to FIG. 6, a solar cell 200 is provided, the solar cell 200 has a front side and an opposing backside, and the backside of the solar cell 200 is connected to the exposed second and fourth contact vias 172, 174 with metal wires 210, thereby electrically connecting the solar cell 200 to the power chip 120 and the driver chip 130. With the backside of the solar cell 200 being electrically connected to the power chip 120 and the driver chip 130, the entire front side of the solar cell 200 can be used to receive solar energy. With this inventive method, the solar cell 200 can be integrated with the power chip 120 and the driver chip 130 with reduced wiring lengths between the solar cell 200 and the power chip 120, between the solar cell 200 and the driver chip 130 and between the power chip 120 and the driver chip 130, resulting in lower power consumption.

The present invention also provides a solar-to-electrical energy conversion system including: a number of functional chips, which are immobilized with a molded layer so that adjacent functional chips are spaced apart at intervals; a first passivation layer over front sides of the functional chips and a surface of the molded layer; a plurality of contact vias in the first passivation layer, which are separately connected to the functional chips; a metal layer over a surface of the first passivation layer, which connects the functional chips through some of the contact vias; a second passivation layer over surfaces of the first passivation layer and the metal layer, wherein surfaces of the remaining contact vias are exposed from the second passivation layer; and a solar cell on a surface of the second passivation layer, wherein a backside of the solar cell is connected to the remaining contact vias through metal wires.

In summary, embodiments of the present invention provide a solar-to-electrical energy conversion system and a method of forming the system. The system includes: providing a solar cell and a number of functional chips, the solar cell having a front side and an opposing backside, each functional chip having a front side and an opposing backside; immobilizing the functional chips with a molded layer so that adjacent functional chips are spaced apart at intervals; forming a first passivation layer over the front sides of the functional chips and a surface of the molded layer; forming a plurality of contact vias in the first passivation layer, which are separately connected to the functional chips; forming a metal layer over a surface of the first passivation layer, which connects the functional chips through some of the contact vias; forming a second passivation layer over the surface of the first passivation layer and a surface of the metal layer and exposing surfaces of the remaining contact vias from the second passivation layer; and bonding the backside of the solar cell to a surface of the second passivation layer and connecting the backside of the solar cell to the remaining contact vias with metal wires. The present invention enables the functional chips to be integrated with the solar cell with shorter transmission paths between the functional chips and between the functional chips and the solar cell, resulting in lower power consumption.

Presented above are merely a few preferred embodiments of the present invention, which do not limit the invention in any way. Changes in any forms made to the principles and teachings disclosed herein, including equivalents and modifications, by any person of ordinary skill in the art without departing from the scope of the invention are intended to fall within the scope of the invention.

1. A method of forming a solar-to-electrical energy conversion system, comprising:
providing a solar cell and a number of functional chips, the solar cell having a front side and a backside opposite to the front side, each of the functional chips having a front side and a backside opposite to the front side;
immobilizing the functional chips with a molded layer, adjacent functional chips are spaced apart at intervals;
forming a first passivation layer over the front sides of the functional chips and a surface of the molded layer;
forming a plurality of contact vias in the first passivation layer, which are separately connected to the functional chips;
forming a metal layer over a surface of the first passivation layer, which connects the functional chips through some of the contact vias;
forming a second passivation layer over the surface of the first passivation layer and a surface of the metal layer and exposing surfaces of the remaining contact vias from the second passivation layer; and
bonding the backside of the solar cell to a surface of the second passivation layer and connecting the backside of the solar cell to the remaining contact vias with metal wires.

2. The method of forming the solar-to-electrical energy conversion system of claim 1, wherein the functional chips include a power chip and a driver chip.

3. The method of forming the solar-to-electrical energy conversion system of claim 1, wherein immobilizing the functional chips with the molded layer comprises:
providing a temporary carrier;
adhesively bonding the front sides of the functional chips to a front side of the temporary carrier with a double-sided adhesive tape, adjacent functional chips are spaced apart at intervals;
forming the molded layer on a surface of the temporary carrier between adjacent functional chips; and
removing the double-sided adhesive tape and the temporary carrier.

4. The method of forming the solar-to-electrical energy conversion system of claim 1, wherein a material of the molded layer comprises epoxy resin.

5. The method of forming the solar-to-electrical energy conversion system of claim 1, wherein adjacent functional chips are spaced apart at intervals smaller than 20 μm.

6. The method of forming the solar-to-electrical energy conversion system of claim 5, wherein adjacent functional chips are spaced apart at 15-μm intervals.

7. The method of forming the solar-to-electrical energy conversion system of claim 1, after the functional chips are immobilized with the molded layer, adjacent functional chips are spaced apart at intervals, the method further comprising:
forming wiring layers on the front sides of the functional chips.

8. The method of forming the solar-to-electrical energy conversion system of claim 7, wherein the contact vias are separately connected to the wiring layers on the functional chips.

9. The method of forming the solar-to-electrical energy conversion system of claim 1, wherein the exposure of the surfaces of the remaining contact vias from the second passivation layer is accomplished by openings formed in the second passivation layer.

10. A solar-to-electrical energy conversion system formable according to the method of claim 1, comprising:
a number of functional chips, which are immobilized with a molded layer, adjacent functional chips are spaced apart at intervals;
a first passivation layer over front sides of the functional chips and a surface of the molded layer;
a plurality of contact vias in the first passivation layer, which are separately connected to the functional chips;
a metal layer over a surface of the first passivation layer, which connects the functional chips through some of the contact vias;
a second passivation layer over surfaces of the first passivation layer and the metal layer, wherein surfaces of the remaining contact vias are exposed from the second passivation layer; and
a solar cell on a surface of the second passivation layer, wherein a backside of the solar cell is connected to the remaining contact vias through metal wires.
